(19) United States
(12) Patent Application Publication
(10) Pub. No.: US 2011/0221061 A1
(43) Pub. Date: Sep. 15, 2011

(54) ANODE FOR AN ORGANIC ELECTRONIC DEVICE

(76) Inventors: Shiva Prakash, Santa Barbara, CA (US); Ines Meinel, Santa Barbara, CA (US)

(21) Appl. No.: 13/127,250

(22) PCT Filed: Dec. 1, 2009
(86) PCT No.: PCT/US09/66202

§ 371 Date: May 3, 2011

Related U.S. Application Data
(60) Provisional application No. 61/118,722, filed on Dec. 1, 2008.

(51) Int. Cl. H01L 23/48; H01L 21/441; H01L 21/445

(52) U.S. Cl. 257/749; 257/763; 438/609; 438/608; 257/E21.477; 257/E21.479; 257/E23.01

(57) ABSTRACT

There is provided an anode for an organic electronic device. The anode has (a) a first layer which is a conducting inorganic material and (b) a second ultrathin layer which is a metal oxide

### RELATED APPLICATION

This application claims priority under 35 U.S.C. §119(e) from U.S. Provisional Application No. 61/188,722 filed Dec. 1, 2008 which is incorporated by reference in its entirety.

### BACKGROUND INFORMATION

1. Field of the Disclosure

This disclosure relates in general to an anode for an electronic device and for the process for forming it.

2. Description of the Related Art

Electronic devices define a category of products that include an active layer. Organic electronic devices have at least one organic active layer. Such devices convert electrical energy into radiation such as light emitting diodes, detect signals through electronic processes, convert radiation into electrical energy, such as photovoltaic cells, or include one or more organic semiconductor layers.

Organic light-emitting diodes (“OLEDs”) are an organic electronic device comprising an organic layer capable of electroluminescence. OLEDs containing conducting polymers can have the following configuration:
anode/EL material/cathode
   with optionally additional layers between the electrodes.

A variety of deposition techniques can be used in forming layers used in OLEDs, including vapor deposition and liquid deposition. Liquid deposition techniques include printing techniques such as ink-jet printing and continuous nozzle printing.

As the devices become more complex and with greater resolution, there is a continuing need for improved materials and processes for these devices.

### SUMMARY

There is provided an anode for an organic electronic device comprising (a) a first layer comprising a conducting inorganic material and (b) a second ultrathin layer comprising a metal oxide.

There is further provided a process for forming an anode, comprising:
providing a substrate,
forming a first anode layer comprising a conducting inorganic material on the substrate; and
forming a second ultrathin anode layer comprising a metal oxide by Atomic Layer Deposition.

There is further provided an organic electronic device comprising:
a substrate,
an anode comprising (a) a first layer comprising a conducting inorganic material and (b) a second ultrathin layer comprising a metal oxide,
at least one organic active layer, and a cathode.

There is further provided a process for forming an organic electronic device, comprising:
providing a TFT substrate;
forming a first anode layer comprising a conducting inorganic material on the TFT substrate;
forming an ultrathin second anode layer comprising a metal oxide on the first layer by Atomic Layer Deposition;
forming at least one organic active layer by a liquid deposition technique;
forming a cathode.

The foregoing general description and the following detailed description are exemplary and explanatory only and are not restrictive of the invention, as defined in the appended claims.

### BRIEF DESCRIPTION OF THE DRAWINGS

The subject matter of the disclosure is illustrated by way of example and not limitation, in the accompanying figures.

FIG. 1 is a graph of leakage current for different devices.

FIG. 2 is a graph of rectification ratio for different devices.

### DETAILED DESCRIPTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Anode, the Process for Forming the Anode, the Organic Electronic Device, and finally Examples.

### 1. Definitions and Clarification of Terms

Before addressing details of embodiments described below, some terms are defined or clarified.

The term “active material” refers to a material which electronically facilitates the operation of the device. Examples of active materials include, but are not limited to, materials which conduct, inject, transport, or block a charge, where the charge can be either an electron or a hole. Examples of inactive materials include, but are not limited to, planarization materials, insulating materials, and environmental barrier materials.

The term “anode” is intended to mean an electrode that is particularly efficient for injecting positive charge carriers. In some embodiments, the anode has a work function of greater than 4.7 eV.

The term “hole-transporting” refers to a layer, material, member, or structure that facilitates migration of positive charge through the thickness of such layer, material, member, or structure with relative efficiency and small loss of charge.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer.

The term “non-conductive,” when referring to a material, is intended to mean a material that allows no significant current to flow through the material. In one embodiment, a non-conductive material has a bulk resistivity of greater than approximately 10⁶ ohm-cm. In some embodiments, the bulk resistivity is great than approximately 10⁸ ohm-cm.

The term “ultrathin” as it refers to a layer is intended to mean a layer having a thickness no greater than 100 Å.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. Anode

An OLED device consists of a multilayer stack having organic, metallic layer anode and cathode layers, where a stack of organic layers is between the metallic layers. The organic stack thickness is very low. The OLED device is prone to having microscopic defects that can act as venues for increased current flow under forward bias (FB) conditions, or even under reverse bias (RB) conditions. Under FB, the defect can draw enough current to make the remaining pixel look darker than neighboring pixels, or even completely dark as in a “dead” pixel. In RB, the defects can result in excessive leakage current or even breakdown of the device.

One way the problem has been approached has been to use thicker organic layers. A second approach has been to surface treat the lower electrode to reduce electrical field concentrations. A third approach is to smooth the surface of the bottom (anode) electrode. However, these approaches can have a detrimental effect on other device properties and/or involve undesired processing steps. Thus, it would be beneficial if a new way could be found to overcome the shorting problem.

The new anode described herein comprises (a) a first layer comprising conductive material and (b) a second ultrathin layer comprising a metal oxide. In some embodiments, the first layer consists essentially of a conductive material and the second layer consists essentially of a metal oxide. The second layer has the correct resistivity to allow for resisting current flow outside the pixel area, to prevent defects discussed above, while allowing current flow in the device to preserve desired device properties.

Any conventional transparent conducting material may be used for the anode so long as the surface can be plasma oxidized. As used herein, the term “surface” as it applies to the anode, is intended to mean the exterior boundaries of the anode material which are exposed and not directly covered by the substrate. The anode layer may be formed in a patterned array of structures having plan view shapes, such as squares, rectangles, circles, triangles, ovals, and the like. Generally, the electrodes may be formed using conventional processes, such as selective deposition using a stencil mask, or blanket deposition and a conventional lithographic technique to remove portions to form the pattern.

In some embodiments, the electrodes are transparent. In some embodiments, the electrodes comprise a transparent conductive material such as indium-tin-oxide (ITO). Other transparent conductive materials include, for example, indium-zinc-oxide (IZO),

Examples of suitable materials include, but are not limited to, indium-tin-oxide (“ITO”). indium-zinc-oxide (“IZO”), aluminum-tin-oxide (“ATO”), aluminum-zinc-oxide (“AZO”), and zirconium-tin-oxide (“ZTO”), zinc oxide, tin oxide, elemental metals, metal alloys, and combinations thereof. The thickness of the electrode is generally in the range of approximately 50 to 150 nm.

The second layer of the anode is an ultrathin layer of a metal oxide. In some embodiments, the layer has a thickness less than 30 Å; in some embodiments, less than 20 Å. In some embodiments, the layer has a thickness in the range of 5-15 Å.

In some embodiments, the metal oxide has a resistivity in the range of 1×10⁶-1×10⁹ ohm-cm for a 50 Å layer; in some embodiments the resistivity is in the range of 1×10⁶-5×10⁷. In some embodiments, the metal oxide is selected from the group consisting of oxides of Group 3-13 metals and oxides of lanthanide metals. In some embodiments, the metal is selected from the group consisting of aluminum, molybdenum, tungsten, nickel, chromium, vanadium, niobium, yttrium, samarium, praseodymium, terbium, and ytterbium.

### 3. Process for Forming the Anode

The first layer of the anode can be formed by any conventional technique. The layer may be formed by a chemical or physical vapor deposition process or spin-coating process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

The ultrathin metal oxide layer can be deposited by any conventional method that will result in a continuous, reproducible layer.

In one embodiment, the process for forming an anode comprises:
providing a substrate,
forming a first anode layer comprising a conducting inorganic material on the substrate; and
forming a second ultrathin anode layer comprising a metal oxide by Atomic Layer Deposition.

Atomic Layer Deposition (ALD) is a proven technique for producing layer by layer growth, and thus is highly reproducible and controllable on a monolayer scale. It is easily scalable and low cost at the process step intended for insertion. The materials that can be deposited by ALD comprise many candidates that will be either insulators or hole transporters, either of which can be incorporated into the device in a manner that allows control of the electrical resistance in the thru-thickness direction.

ALD can be defined as a film deposition technique that is based on the sequential use of self-terminating gas-solid reactions. In the ALD process, two reactants are typically used. Each reactant is carried by nitrogen gas one after the other into the chamber resulting in adsorption onto the sample surface. Between reactant pulses, the chamber is evacuated to prevent gas phase reactions between the reactants. The reaction between the adsorbed reactants takes place on the substrate surface, followed by desorption of gaseous reaction by-products. The surface reaction is reaction-limited, and so mass flow is not rate controlling. Thus the film produced is highly conformal and monolayer in thickness. The ALD-grown second layer will be chosen to satisfy the resistivity criteria that provides the best performance without defects.

Some non-limiting examples of metal oxides and the reactants that are used to form them are given in the table below.

| Material | Reactant A | Reactant B |
|---|---|---|
| MgO | MgCp₂ | H₂O |
| Al₂O₃ | AlCl₃ | H₂O |
| | AlMe₃ | H₂O |
| | Al(OEt)₃ | H₂O |
| Sc₂O₃ | Sc(thd)₃ | O₃ |
| NiO | NiCp₂ | H₂O |
| | Ni(acac)₂ | O₂ |
| CuO | Cu(acac)₂ | O₂ |
| ZrO₂ | ZrCl₄ | H₂O |
| MoO₃ | MoO₂(acac)₂ | H₂O |
| | Mo(CO)₆ | O₂ |
| | bis(tert-butylamido)-bis | O₂ |
| | (dimethylamido)Mo | |
| | complexes | |
| Sm₂O₃ | Sm(thd)₃ | O₃ |

Cp = cyclopentadiene
thd = 2,2,6,6-tetramethylhepan-3,5-dione
acac = acetylacetonate

The ALD process is generally carried out by controlling several parameters. Pulse is the time in seconds the reactant material is exposed to the carrier gas flow going into chamber. In some embodiments, the pulse is in the range of 0.1 to 1.0 second. Exposure is the time in seconds each reactant is kept in the chamber with flow off, to allow it to adsorb/react on the surface. In some embodiments, the exposure is 5-50 seconds. Pump is the time in seconds each reactant is pumped out after its exposure step before the other reactant is let in. In some embodiments, the pump time is in the range of 3-20 seconds. As noted above, each reactant in ALD comes separately. Cycles is the number of pairs of cycles of exposure. In some embodiments, the number of cycles is in the range of 5-20. Flow is the carrier gas flow rate. In some embodiments, the flow is in the range of 10-50 standard cubic cm per minute (SCCM).

### 4. Organic Electronic Device

The term “organic electronic device” or sometimes just “electronic device” is intended to mean a device including one or more organic semiconductor layers or materials. An organic electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

In some embodiments, the organic electronic device comprises:
a substrate,
an anode comprising (a) a first layer comprising a conducting inorganic material and (b) a second ultrathin layer comprising a metal oxide,
at least one organic active layer, and
a cathode.

The substrate is a base material that can be either rigid or flexible and may be include one or more layers of one or more materials, which can include, but are not limited to, glass, polymer, metal or ceramic materials or combinations thereof. In some embodiments, the substrate is glass.

In some embodiments, the substrate is a TFT substrate. TFT substrates are well known in the electronic art. The base support may be a conventional support as used in organic electronic device arts. The base support can be flexible or rigid, organic or inorganic. In some embodiments, the base support is transparent. In some embodiments, the base support is glass or a flexible organic film. The TFT array may be located over or within the support, as is known. The support can have a thickness in the range of about 12 to 2500 microns.

The term “thin-film transistor” or “TFT” is intended to mean a field-effect transistor in which at least a channel region of the field-effect transistor is not principally a portion of a base material of a substrate. In one embodiment, the channel region of a TFT includes a-Si, polycrystalline silicon, or a combination thereof. The term “field-effect transistor” is intended to mean a transistor, whose current carrying characteristics are affected by a voltage on a gate electrode. A field-effect transistor includes a junction field-effect transistor (JFET) or a metal-insulator-semiconductor field-effect transistor (MISFET), including a metal-oxide-semiconductor field-effect transistor (MOSFETs), a metal-nitride-oxide-semiconductor (MNOS) field-effect transistor, or the like. A field-effect transistor can be n-channel (n-type carriers flowing within the channel region) or p-channel (p-type carriers flowing within the channel region). A field-effect transistor may be an enhancement-mode transistor (channel region having a different conductivity type compared to the transistor's S/D regions) or depletion-mode transistor (the transistor's channel and S/D regions have the same conductivity type).

The TFT substrate also includes a surface insulating layer, which can be an organic planarization layer or an inorganic passivation layer. Any materials and thicknesses known to be useful for these layer can be used.

The first and second layer of the new anode are deposited on the substrate as discussed above.

The organic layer or layers include one or more of a buffer layer, a hole transport layer, a photoactive layer, an electron transport layer, and an electron injection layer. The layers are arranged in the order listed.

The term “organic buffer layer” or “organic buffer material” is intended to mean electrically conductive or semiconductive organic materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Organic buffer materials may be polymers, oligomers, or small molecules, and may be in the form of solutions, dispersions, suspensions, emulsions, colloidal mixtures, or other compositions.

The organic buffer layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The organic buffer layer can comprise charge transfer compounds, and the like, such as copper phthalocyanine and the tetrathiafulvalene-tetracyanoquinodimethane system (TTF-TCNQ). In one embodiment, the organic buffer layer is made from a dispersion of a conducting polymer and a colloid-forming polymeric acid. Such materials have been described in, for example, published U.S. patent applications 2004-0102577, 2004-0127637, and 2005/205860. The organic buffer layer typically has a thickness in a range of approximately 20-200 nm.

Examples of hole transport materials have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. The hole transport layer typically has a thickness in a range of approximately 40-100 nm. Although light-emitting materials may also have some charge transport properties, the term “hole transport layer” is not intended to include a layer whose primary function is light emission.

“Photoactive” refers to a material that emits light when activated by an applied voltage (such as in a light emitting diode or chemical cell) or responds to radiant energy and generates a signal with or without an applied bias voltage (such as in a photodetector). Any organic electroluminescent (“EL”) material can be used in the photoactive layer, and such materials are well known in the art. The materials include, but are not limited to, small molecule organic fluorescent compounds, fluorescent and phosphorescent metal complexes, conjugated polymers, and mixtures thereof. The photoactive material can be present alone, or in admixture with one or more host materials. Examples of fluorescent compounds include, but are not limited to, naphthalene, anthracene, chrysene, pyrene, tetracene, xanthene, perylene, coumarin, rhodamine, quinacridone, rubrene, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Examples of conjugated polymers include, but are not limited to poly(phenylenevinylenes), polyfluorenes, poly(spirobifluorenes), polythiophenes, poly(p-phenylenes), copolymers thereof, and mixtures thereof. The photoactive layer typically has a thickness in a range of approximately 50-500 nm.

“Electron Transport” means when referring to a layer, material, member or structure, such a layer, material, member or structure that promotes or facilitates migration of negative charges through such a layer, material, member or structure into another layer, material, member or structure. Examples of electron transport materials which can be used in the optional electron transport layer 140, include metal chelated oxinoid compounds, such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. The electron-transport layer typically has a thickness in a range of approximately 30-500 nm. Although light-emitting materials may also have some charge transport properties, the term “electron transport layer” is not intended to include a layer whose primary function is light emission.

As used herein, the term “electron injection” when referring to a layer, material, member, or structure, is intended to mean such layer, material, member, or structure facilitates injection and migration of negative charges through the thickness of such layer, material, member, or structure with relative efficiency and small loss of charge. The optional electron-transport layer may be inorganic and comprise BaO, LiF, or Li₂O. The electron injection layer typically has a thickness in a range of approximately 20-100 Å.

The cathode can be selected from Group 1 metals (e.g., Li, Cs), the Group 2 (alkaline earth) metals, the rare earth metals including the lanthanides and the actinides. The cathode a thickness in a range of approximately 300-1000 nm.

An encapsulating layer can be formed over the array and the peripheral and remote circuitry to form a substantially complete electrical device.

In some embodiments, a process for forming an organic electronic device, comprises:
providing a TFT substrate;
forming a first layer comprising a conducting inorganic material on the TFT substrate;
forming an ultrathin second layer comprising a metal oxide on the first layer by Atomic Layer Deposition;
forming at least one organic active layer by a liquid deposition technique;
forming a cathode.

In liquid deposition, an organic active material is formed into a layer from a liquid composition. The term “liquid composition” is intended to mean a liquid medium in which a material is dissolved to form a solution, a liquid medium in which a material is dispersed to form a dispersion, or a liquid medium in which a material is suspended to form a suspension or an emulsion. The term “liquid medium” is intended to mean a liquid material, including a pure liquid, a combination of liquids, a solution, a dispersion, a suspension, and an emulsion. Liquid medium is used regardless whether one or more solvents are present.

Any known liquid deposition technique can be used, including continuous and discontinuous techniques. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

In some embodiments, the buffer layer, the hole transport layer and the photoactive layer are formed by liquid deposition techniques. The electron transport layer, the electron injection layer and the cathode are formed by vapor deposition techniques.

### EXAMPLES

The concepts described herein will be further described in the following examples, which do not limit the scope of the invention described in the claims.

### Examples

These examples demonstrate the performance of a device having the new anode describe herein.

The devices had the following structure:
substrate=glass
1^{st} anode layer=ITO with a thickness of 180 nm
2^{nd} anode layer=alumina formed by ALD
buffer layer=layer formed from an aqueous dispersion of an electrically conductive polymer and a polymeric fluorinated sulfonic acid (such materials have been described in, for example, published U.S. patent applications US 2004/0102577, US 2004/0127637, and US 2005/0205860) with a thickness of 40 nm
hole transport layer=an arylamine-containing copolymer (such materials have been described in, for example, published U.S. patent application US 2008/0071049) with a thickness of 20 nm
photoactive layer=13:1 host:dopant, where the host is an anthracene derivative (such materials have been described in, for example, U.S. Pat. No. 7,023,013) and the dopant is an arylamine compound (such materials have been described in, for example, U.S. published patent application US 2006/0033421) with a thickness of 32 nm
electron transport layer=a metal quinolate derivative with a thickness of 10 nm
cathode=LiF/Al (1/100 nm)
   In Example 1, the alumina layer had a thickness of 7 Å, with the following ALD conditions:

| Reactant | Pulse | Exposure | Pump | cycles | flow |
|---|---|---|---|---|---|
| water | 0.15 | 10 | 5 | 7 | 20 |
| AlMe₃ | 0.15 | 10 | 10 | | 20 |

In Example 2, the alumina layer had a thickness of 12 Å, with the following ALD conditions:

| Reactant | Pulse | Exposure | Pump | cycles | flow |
|---|---|---|---|---|---|
| water | 0.15 | 10 | 5 | 12 | 20 |
| AlMe₃ | 0.15 | 10 | 10 | | 20 |

In Comparative Example A, there was no second anode layer.

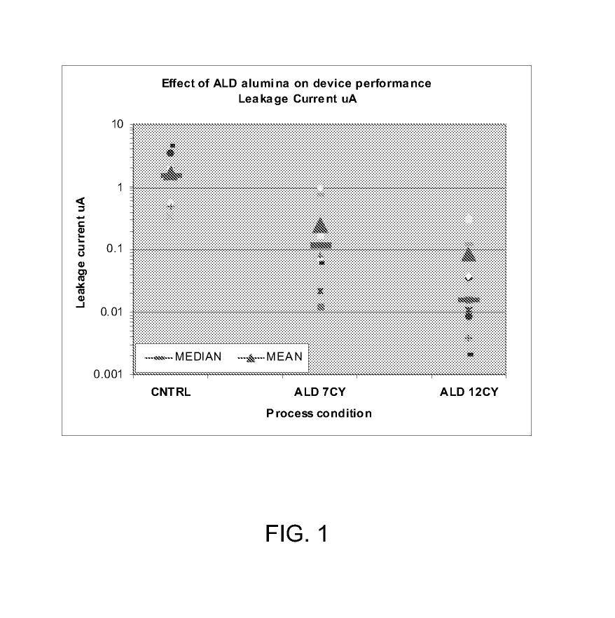

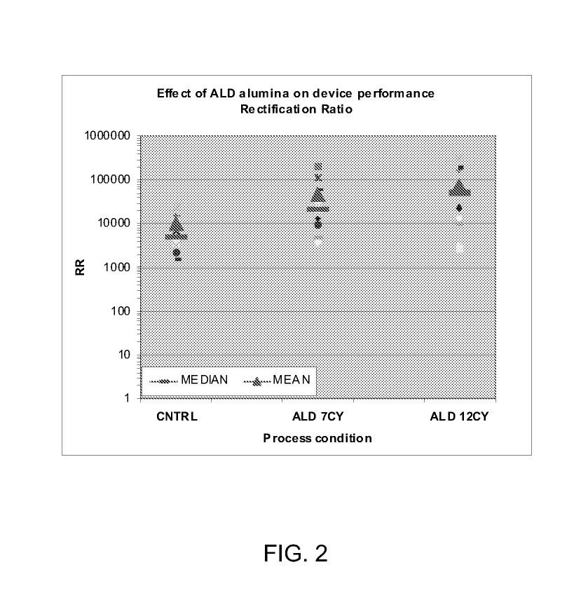

The leakage current of the devices is shown in FIG. 1. The rectification ratios are shown in FIG. 2. It can be seen that both the leakage current and rectification ratio were markedly better for Examples 1 and 2 as compared to the Comparative Example with no second anode layer.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

What is claimed is:

1. An anode for an organic electronic device comprising (a) a first layer comprising a conducting inorganic material and (b) a second ultrathin layer comprising a metal oxide.

2. The anode of claim 1, wherein the conducting inorganic material is selected from the group consisting of indium-tin-oxide, indium-zinc-oxide, aluminum-tin-oxide, aluminum-zinc-oxide, and zirconium-tin-oxide.

3. The anode of claim 1, wherein the metal oxide is selected from the group consisting of oxides of Group 3-13 metals and lanthanide metals.

4. The anode of claim 1, wherein the metal oxide is selected from the group consisting of aluminum oxides, molybdenum oxides, vanadium oxides, chromium oxides, tungsten oxides, nickel oxides, niobium oxides, yttrium oxides, samarium oxides, praseodymium oxides, terbium oxides and ytterbium oxides.

5. A process for forming an anode, comprising:
providing a substrate,
forming a first anode layer comprising a conducting inorganic material on the substrate; and
forming a second ultrathin anode layer comprising a metal oxide by Atomic Layer Deposition.

6. An organic electronic device comprising:
a substrate,
an anode comprising (a) a first layer comprising a conducting inorganic material and (b) a second ultrathin layer comprising a metal oxide,
at least one organic active layer, and
a cathode.

7. The device of claim 6, wherein the conducting inorganic material is selected from the group consisting of indium-tin-oxide, indium-zinc-oxide, aluminum-tin-oxide, aluminum-zinc-oxide, and zirconium-tin-oxide.

8. The device of claim 6, wherein the substrate is a TFT substrate.

9. The device of claim 6, wherein the metal oxide is selected from the group consisting of oxides of Group 3-13 metals and lanthanide metals.

10. The device of claim 6, wherein the metal oxide is selected from the group consisting of aluminum oxides, molybdenum oxides, vanadium oxides, chromium oxides, tungsten oxides, nickel oxides, niobium oxides, yttrium oxides, samarium oxides, praseodymium oxides, terbium oxides and ytterbium oxides.

11. A process for forming an organic electronic device, comprising:
providing a TFT substrate;
forming a first anode layer comprising a conducting inorganic material on the TFT substrate;
forming an ultrathin second anode layer comprising a metal oxide on the first layer by Atomic Layer Deposition;
forming at least one organic active layer by a liquid deposition technique;
forming a cathode.
